(19) United States
(12) Patent Application Publication
(10) Pub. No.: US 2018/0195196 A1
(43) Pub. Date: Jul. 12, 2018

(54) PROTECTIVE OXIDE COATING WITH REDUCED METAL CONCENTRATIONS

(71) Applicant: MKS Instruments, Inc., Andover, MA (US)

(72) Inventors: Chiu-Ying Tai, Chelmsford, MA (US); Atul Gupta, Lexington, MA (US); Kevin Wenzel, Belmont, MA (US); Glenn Stanton, Gloucester, MA (US)

(21) Appl. No.: 15/400,635

(22) Filed: Jan. 6, 2017

(51) Int. Cl. C25D 11/12; C25D 11/02; H01J 37/32

(52) U.S. Cl. CPC C25D 11/12; H01J 37/32495; C25D 11/026

(57) ABSTRACT

A method is introduced for creating a protective oxide layer over a surface of a metallic structure for use in a semiconductor processing system. The method includes providing the metallic structure, anodizing the surface of the metallic structure to form an anodization layer on the surface, and converting, using a plasma electrolytic oxidation process, at least a portion of the anodization layer to form the protective oxide layer.

### TECHNICAL FIELD

This technology relates to fabricating protective layers over a metallic structure using an anodization process followed by a plasma electrolytic oxidation (PEO) process. The resulting protective layers have reduced levels of metal contaminants and are therefore more useful in semiconductor processing.

### BACKGROUND

Plasmas are often used to activate gases placing them in an excited state with enhanced reactivity. In some cases, the gases are excited to produce plasma containing ions, free radicals, electrons, atoms and molecules. Plasmas are used for numerous industrial and scientific applications including processing materials such as semiconductor work pieces (e.g., wafers), powders, and other gases, such as deposition precursors or other reactant gases that need to be dissociated. The parameters of plasmas and the conditions of the exposure of plasmas to the material being processed vary widely depending on the applications.

Plasma reactors for processing semiconductor wafers may form a plasma within a chamber containing the wafer, or they may receive excited gases produced by a reactive gas generator located upstream of the chamber. The preferred location of plasma generation relative to the wafer location depends on the process.

In some situations, the wafer and the plasma chamber surfaces can be damaged by exposure to chemically corrosive plasmas, which may create chemical contamination and particle generation, shorten the product life and increase cost of ownership. Accordingly, remote plasma sources are sometimes used to reduce wafer and chamber damage by generating plasma outside the process chamber and then delivering activated gases produced by the plasma to the processing chamber for processing the wafer.

Reactive gas generators generate plasmas by, for example, applying an electric potential of sufficient magnitude to a plasma gas, or a mixture of gases, to ionize at least a portion of the gas. Plasmas are typically contained within chambers having chamber walls that are composed of metallic materials such as aluminum, or dielectric materials such as quartz, sapphire, yttrium oxide, a zirconium oxide, aluminum oxide, and/or an aluminum nitride. The plasma chamber can include a metal vessel having walls coated with a dielectric material.

In some applications, a plasma or an excited gas may not be compatible with the reactive gas generator and/or the semiconductor processing system. For example, during semiconductor manufacturing, ions or atoms of fluorine or fluorocarbons may be used for etching or removing silicon or silicon oxides from surfaces of semiconductor wafers or for cleaning process chambers. Because the ions generated in a plasma can accelerate into process chamber materials due to surrounding electric fields, thereby causing significant damage to the process chamber materials, remote plasma sources have been used to generate highly reactive radicals for these processes to avoid damaging the process chamber. Although the use of a remote plasma source reduces corrosion/erosion in the process chamber, some corrosion/erosion still occurs in the remote plasma source.

In some applications, active atomic species are used in a fabrication process within a plasma chamber. For example, atomic hydrogen can be used in native oxide cleaning processes and photoresist ashing. In these cases, atomic hydrogen can be produced by dissociating H₂ or NH₃ with a plasma in a plasma chamber. Atomic oxygen can also be used to remove photoresist from a semiconductor wafer by converting the photoresist into volatile CO₂ and H₂O byproducts. In these cases, atomic oxygen can be produced by dissociating O₂ (or a gas containing oxygen) with a plasma in a plasma chamber of a reactive gas generator. Atomic fluorine is often used in conjunction with atomic oxygen because the atomic fluorine accelerates the photoresist removal process. Fluorine is generated by, for example, dissociating NF₃ or CF₄ with the plasma in the plasma chamber. Fluorine, however, is highly corrosive and can adversely react with various materials used for chambers, such as aluminum.

Generally, a problem that plagues many different types of equipment used in semiconductor fabrication, including plasma chambers, is metal contamination. In applications that rely on active atomic species such as atomic hydrogen, a metal-contaminated surface can change the interaction between the plasma-facing surface and the active atomic species and result in an increase of surface recombination of atomic radicals inside the semiconductor equipment, such as on the surface of a plasma applicator of a remote plasma source. The metal-contaminated surface can lead to the reduction of manufacturing performance, such as degradation of the deposition rate.

In addition, certain surface defects in the plasma equipment component wall, such as crazings/cracks, pits and surface inclusions, can be enhanced after exposure to plasma that may cause further surface damages and particle generations. These enhanced defects can result in shortened life time of the semiconductor equipment.

These problems are not limited to plasmas in plasma processing chambers. Similar problems can also occur in semiconductor processing chambers, where reactive gases (or gaseous radicals) and/or corroding liquid reagents in the chambers can cause metallic contamination on the chamber walls and enhance certain physical defects.

Existing solutions to address these problems include coating a surface of the processing chamber with an oxide layer that is produced by a typical PEO process. However, the resulting oxide layer often has increased metal contents due to the high voltage and/or high power involved in the coating process. For example, the high power used in a coating process often causes an increased amount of metal elements to flow from the base alloy in the plasma chamber material to the coating surface through discharge channels that can form during the plasma electrolytic oxidation process. Higher metallic contaminants on the surface of the plasma-facing coating result in higher radical recombination, thus degraded process performance.

A need therefore exists for improved protective coatings that are low in radical recombination and less susceptible to the corrosive effects of excited gases located in a semiconductor processing chamber.

### SUMMARY

In one aspect, a method for fabricating a protective oxide layer over a surface of a metallic structure is provided. The method can be used in a semiconductor processing system. The method includes providing the metallic structure and anodizing the surface of the metallic structure to form an anodization layer on the surface. The method also includes converting, using a plasma electrolytic oxidation (PEO) process, at least a portion of the anodization layer to form the protective oxide layer.

In some embodiments, the method further includes converting, using the plasma electrolytic oxidation process, substantially an entire thickness of the anodization layer to form the protective oxide layer over the surface of the metallic structure.

In some embodiments, the surface of the metallic structure comprises at least one of aluminum, magnesium, titanium, or yttrium. In some embodiments, the surface of the metallic structure is directly covered by the protective oxide layer from the plasma electrolytic oxidation process at a first location and directly covered by the anodization layer from the anodizing at a second location.

In some embodiments, the method provides a minimized metal concentration of the protective oxide layer to reduce recombination of atomic species on a surface of the protective oxide layer. In some embodiments, the protective oxide layer formed by the method is substantially free of one or more defects in the anodization layer.

In some embodiments, the method further includes forming a plurality of surface ridges protruding from the protective oxide layer. The plurality of surface ridges can substantially align with corresponding ones of a plurality of defects in the anodization layer.

In another aspect, a coated metallic structure used in a plasma processing equipment is provided. The coated metallic structure includes a metallic structure and a protective oxide layer formed over a surface of the metallic structure. The protective oxide layer is formed by anodizing the surface of the metallic structure to generate an anodized layer and converting substantially all of the anodized layer using a plasma electrolytic oxidation process. The protective oxide layer is characterized by a plurality of surface ridges protruding from the protective oxide layer.

In some embodiments, the protective oxide layer on the coated metallic structure is generally planar. In some embodiments, the plurality of surface ridges of the protective oxide layer are substantially aligned with respective ones of a plurality of cracks formed in the anodized layer. In some embodiments, a planar surface of the protective oxide layer on the coated metallic structure is formed by mechanical processing.

In some embodiments, the protective oxide layer formed from the plasma electrolytic oxidation process directly covers the surface of the metallic structure at a first surface location and the anodized layer formed from the anodizing directly covers the surface of the metallic structure at a second surface location.

In yet another aspect, a component comprising a metallic layer and a protective oxide layer over a surface of the metallic layer is provided. The component is formed by a process that includes providing the metallic layer, forming an anodization layer on the surface of the metallic layer by anodizing the surface, and converting, using a plasma electrolytic oxidation process, at least a portion of the anodization layer to form the protective oxide layer over the surface of the metallic layer.

In some embodiments, a metal concentration of the protective oxide layer is minimized to reduce recombination of atomic species on a surface of the protective oxide layer.

In some embodiments, the metallic layer comprises an aluminum alloy. In some embodiments, the surface of the metallic layer comprises at least one of aluminum, magnesium, titanium, or yttrium.

In some embodiments, forming an anodization layer includes anodizing the surface by a hard anodization process. In some embodiments, a thickness of the anodization layer is less than 130 microns. In some embodiments, the thickness of the anodization layer is between about 12 to about 120 microns.

In some embodiments, converting at least a portion of the anodization layer further includes converting, using the plasma electrolytic oxidation process, substantially an entire thickness of the anodization layer to form the protective oxide layer over the surface of the metallic layer.

In some embodiments, the protective oxide layer is substantially free of one or more defects in the anodization layer. In some embodiments, the protective oxide layer includes a partially crystallized dense structure formed adjacent to the metallic layer. In some embodiments, the protective oxide layer is corrosion and erosion resistant.

In some embodiments, the protected oxide layer is in contact with a plasma in a plasma processing chamber. In some embodiments, the protected oxide layer is in contact with a reactive gas or gaseous radicals in a semiconductor processing chamber. In some embodiments, the protected oxide layer is in contact with a corroding liquid reagent in a semiconductor processing chamber.

### BRIEF DESCRIPTION OF THE DRAWINGS

In the drawings, like reference characters generally refer to the same parts throughout the different views. Also the drawings are not necessarily to scale, emphasis instead being placed upon illustrating the principles of the disclosure.

FIG. 1 is flow chart illustrating a method for creating a protective oxide layer having a reduced metal concentration over a surface of a metallic structure, according to an illustrative embodiment.

FIG. 2A is an exemplary scanning electron microscopy (SEM) image of a curved metallic structure with an anodization coating on the surface of the structure, according to an illustrative embodiment.

FIG. 2B is another exemplary SEM image of a curved metallic structure with an anodization coating on the surface of the structure, according to an illustrative embodiment.

FIG. 3A is an exemplary SEM image of a curved metallic structure with a protective oxide layer formed by PEO after anodization of the metallic structure, according to an illustrative embodiment.

FIG. 3B is another exemplary SEM image of a metallic structure with a protective oxide layer formed by PEO after anodization of the metallic structure, according to an illustrative embodiment.

FIG. 4A is an exemplary cross-sectional view of an SEM image of a curved metallic structure with an anodization layer on the surface of the metallic structure, according to an illustrative embodiment.

FIG. 4B is an exemplary cross-sectional view of an SEM image of a curved metallic structure with a protective oxide layer formed by PEO after anodization of the metallic structure, according to an illustrative embodiment.

FIG. 5A is an exemplary cross-sectional view of an SEM image of a curved metallic structure with a protective oxide layer formed by a traditional PEO process on the un-anodized metallic structure.

FIG. 5B is an exemplary cross-sectional view of an SEM image of a curved metallic structure with a protective oxide layer formed by PEO after anodization of the metallic structure, according to an illustrative embodiment.

FIG. 6 is a graph of concentrations of iron, manganese, and copper as a function of depth in three samples, according to an illustrative embodiment.

FIG. 7 is an illustration of different layering structures that can be formed by the method of FIG. 1.

FIG. 8A is partial schematic representation of a reactive gas generator system for exciting gases that includes an exemplary plasma chamber, according to an illustrative embodiment.

FIG. 8B is partial schematic representation of an in-situ plasma system, according to an illustrative embodiment.

### DETAILED DESCRIPTION

In plasma generators utilizing metallic materials (e.g. aluminum) for the plasma chamber, a plasma electrolytic oxidation (PEO) process can be applied to chamber surfaces to increase corrosion/erosion resistance. Methods for forming oxide coatings using PEO processes are described in U.S. patent application Ser. No. 12/794,470, U.S. Pat. No. 8,888,982, filed Jun. 4, 2010, and entitled “Reduction of Copper or Trace Metal Contamination in Plasma Electrolytic Oxidation Coatings,” the entire contents of which is incorporated herein by reference.

PEO (also referred to as micro arc oxidation) is a term describing electrochemical processes for creating an oxide layer on the surface of metals. Generally, in a PEO process, an oxide layer is created by immersing a metal substrate (e.g., an aluminum alloy) in a low concentrate alkaline electrolytic solution and passing a pulsed AC current through the electrolytic solution. A plasma discharge is formed on the substrate surface in response to the pulsed AC current. The discharge converts the metal surface into a dense, hard oxide (e.g., predominantly alumina or aluminum oxide in the case where the substrate is aluminum). Protective layers created using PEO processes on metal surfaces are harder, less porous, and more resistant to corrosion/erosion than protective layers produced using conventional anodic oxidation. For example, the corrosion/erosion rates of coatings produced by PEO could be 2-5 times lower than corrosion/erosion rates of similar coatings produced by type III hard anodization. In comparison with conventional anodization carried out using low electrical potentials (typically several tens of volts), PEO involves the application of high electrical potentials (typically several hundreds of volts). The high electrical potentials applied in PEO result in electrical discharges that produce a plasma at the surface of the object. The plasma thus modifies and enhances the structure of the oxide layer. During PEO, the oxide grows outward from the original metal surface of the object and inward from the original metal surface by converting the metal in the object into oxide. As a result, elements within the metal are more easily incorporated into the PEO processed oxide than through the conventional anodization process. In general, an oxide layer formed using a PEO process primarily have three layers: an external layer, a partially crystallized layer, and a transition layer. The external layer occupies approximately 30%-40% of the total thickness of the oxide layer. The partially crystallized layer is located between the external layer and the transition layer. The transition layer is a thin layer located directly on the metal substrate. Various electrolytes can be used to form the dense oxide layer in a PEO process.

Applicants discovered that although an oxide layer formed by a PEO process on an object of metallic alloy (e.g. an aluminum alloy) has increased corrosion/erosion resistance, the process of forming the oxide layer may result in a higher metal concentration on a surface of the oxide layer than in the metallic object (i.e., the base substrate layer). Specifically, the peak metal concentration in the oxide layer can be higher than the metal concentration in the underlying metallic object. For example, Applicants have observed that metal concentrations, such as copper (Cu), iron (Fe) and manganese (Mn), in oxide coatings produced using a PEO process are highest at or near the surface of the coating and generally decrease with increasing depth. As explained above, small concentrations of metals can cause defects in semiconductor processing due to the metals' high diffusion rate in silicon. Metals concentrated on a surface of an object, such as on a chamber wall of a semiconductor processing system, can be especially problematic due to the risk of transferring metal from the object to a sample, such as to a wafer, or to other semiconductor processing equipment. Thus, despite the improved corrosion/erosion resistance offered by an oxide coating on an object produced using a PEO process, an increased metal concentration at a surface of the oxide coating can render the object unsuitable for use in some semiconductor processing environments due to the increased risk of surface radical recombination and/or metal contamination. Accordingly, the present invention is directed to methods of manufacturing a more robust protective PEO oxide coating having a lower radical recombination on the surface and a reduced metal concentration.

In some embodiments of the present invention, an oxide layer of a PEO process is formed over an anodized metallic structure (e.g. a metal substrate). For example, a PEO process can be applied on a surface of a metallic structure that is already covered by an anodization layer. In an exemplary PEO process of the present invention, an oxide layer can be created by immersing an anodized metallic structure in a low concentrate alkaline electrolytic solution, and passing a pulsed AC current through the electrolytic solution. A plasma discharge is formed on the surface of the anodized metallic structure in response to the pulsed AC current. The discharge converts the surface into a dense, hard oxide. Various electrolytic solutions can be used to form the dense oxide layer in a PEO process. Some PEO processes are commercially available.

Embodiments described herein are useful for creating protective layers over the surfaces of objects used in semiconductor processing. For example, a protective layer covering an interior wall of a plasma source in a semiconductor processing system can reduce surface erosion (e.g., melting, vaporization, sublimation, corrosion, sputtering of the material beneath the protective layer) of the interior wall. Reducing surface erosion ultimately reduces particle generation and contamination of processes performed in the semiconductor processing system. As another example, the protective layer can also reduce the loss of reactive gases that can otherwise occur due to surface reaction or recombination of the reactive gas on the interior wall of the plasma source. In yet another example, the protective layer can be used in plasma confinement chambers and/or on surfaces immediately downstream from the plasma confinement chambers, such as transport tubes, exit flanges, showerheads, etc. In some instances, the protective layer can be used in a semiconductor wet process to protect surfaces in contact with or facing a corroding liquid reagent in a processing chamber.

The protective layer also broadens the types of plasma chemistries that can be operated in a plasma source. The protective layer enables the plasma chamber to be more capable of operating (e.g., producing fewer contaminants) in hydrogen, oxygen or nitrogen based chemistries (e.g., H₂O, H₂, O₂, N₂, NH₃), halogen based chemistries (e.g., NF₃, CF₄, C₂F₆, C₃F₈, SF₆, Cl₂, ClF₃, F₂, Cl₂, HCl, BCl₃, ClF₃, Br₂, HBr, I₂, HI), and in a mixture of halogen, hydrogen, oxygen or nitrogen based chemistries, and/or in a rapid cycling environment of the chemistries. The protective layer therefore extends operation of the plasma sources to higher power levels, improves the dielectric breakdown voltage of the object through the presence of the layer, and ultimately lowers product cost and cost of ownership.

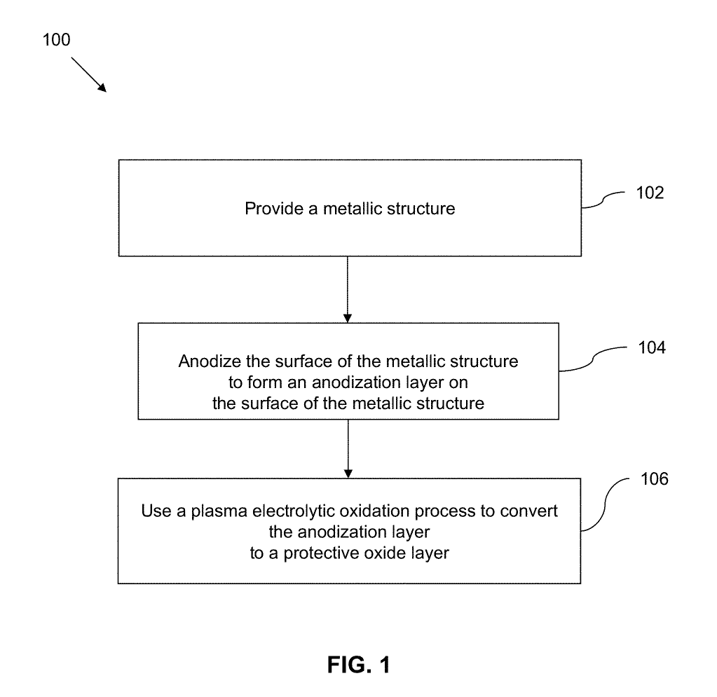

FIG. 1 is an exemplary flow chart illustrating a method 100 for creating a protective oxide layer having a reduced metal concentration over a surface of a metallic structure, according to an illustrative embodiment. As shown in FIG. 1, a metallic structure is provided (step 102). In some embodiments, the metallic structure comprises an aluminum alloy. In some embodiments, the metallic structure comprises at least one of aluminum, magnesium, titanium or yttrium, or a combination of two or more of these metals. In some embodiments, the metallic structure includes a metallic layer that is formed on top of an object or a base structure made of other metals or non-metal materials such as ceramics or dielectric materials. In some embodiments, the metallic structure is a component used in a semiconductor process, such as a plasma chamber. In some embodiments, the metallic structure is a substrate or base component. In one example, the metallic structure is made of aluminum 6061 alloy (Al 6061).

A surface of the metallic structure is anodized using an anodization process (step 104). Anodizing is an electrochemical process that converts a metal surface into an anodic oxide finish. Anodizing can be accomplished by immersing a metallic substrate in an acid electrolyte bath and passing an electric current though the metallic substrate. Anodization can be carried out using low electrical potentials (typically several tens of volts).

An anodization layer can be formed on the surface of the metallic structure as the result of applying an anodization process on the metallic structure. The thickness and other properties of the anodization layer are determined by a number of processing factors, including the applied current/voltage, working temperature, electrolyte concentration, and/or acidity range of the anodization process used. For example, the anodization process can use one or more different types of acid to generate the anodization layer, such as chromic acid, phosphoric acid, oxalic acid, sulfuric acid, or a mixed acid solution. Generally, three types of anodized layer can be produced under different anodization working conditions as shown in Table 1 below.

TABLE 1
Different types of anodization layer formed by different
parameters of the anodization process.

| (Typical range) | Type I | Type II | Type III |
|---|---|---|---|
| Operation temperature (° C.) | 38~42 | 15~25 | −5~25 |
| Current density (A/dm²) | 0.3~0.4 | 0.9~1.3 | 2.5~6.5 |
| Thickness (μm) | Up to 10 | 2~25 | 12~120 |

The anodization layer formed at step 104 can be Type I, II, or III. The applied current/voltage, chemical concentration, and/or working temperature used in the anodization process can vary in a wide range. In some embodiments, a type III hard anodization coating is formed on the base metallic structure. For example, a clear hard anodized layer defined by the anodic coating specification MIL-A-8625 Type III Class 1 can be formed over a metallic structure. In one example, the thickness of a hard anodization layer is about 30 μm to about 50 μm. The surface of the anodization layer can remain unsealed or without any other post treatment. The unsealed pores in the anodization coating provide pre-existed channels for the subsequent PEO coating process to start, as described below. This can help to generate less reacting heat and lower local pressure. In alternative embodiments, the surface of the anodization layer is sealed.

The surface of the anodized metallic structure (i.e., a metallic structure with an anodization layer thereon) can be oxidized using a plasma electrolytic oxidation (PEO) process (step 106), which produces a protective oxide layer on that surface. In some embodiments, the PEO process converts substantially the entire anodization layer to the protective oxide layer. In some embodiments, the PEO process converts through and beyond the entire thickness of the anodization layer into the underlying base metallic structure. In this case, a portion of the base metallic structure is converted to the protective oxide layer. In some embodiments, the PEO process converts a partial thickness of the anodization layer. For example, where the PEO process cannot reach certain locations of the anodized metallic structure, such as deep holes with small diameters, the anodization layer on the surface of the base metallic structure remains intact.

In one exemplary implementation of the PEO process of step 106, a metallic structure with an anodization layer (i.e., an anodized metallic structure) is immersed in an alkaline electrolyte to initiate the PEO process. The electrolyte can include a low-concentration alkaline solution such as KOH or NaOH. The resulting structure is then exposed to bipolar AC power within +/−1 kV range for a suitable duration to ensure the growth of PEO coating. For example, a pulsed AC current can be applied with an on and off duration of between about 0 to about 2000 microseconds.

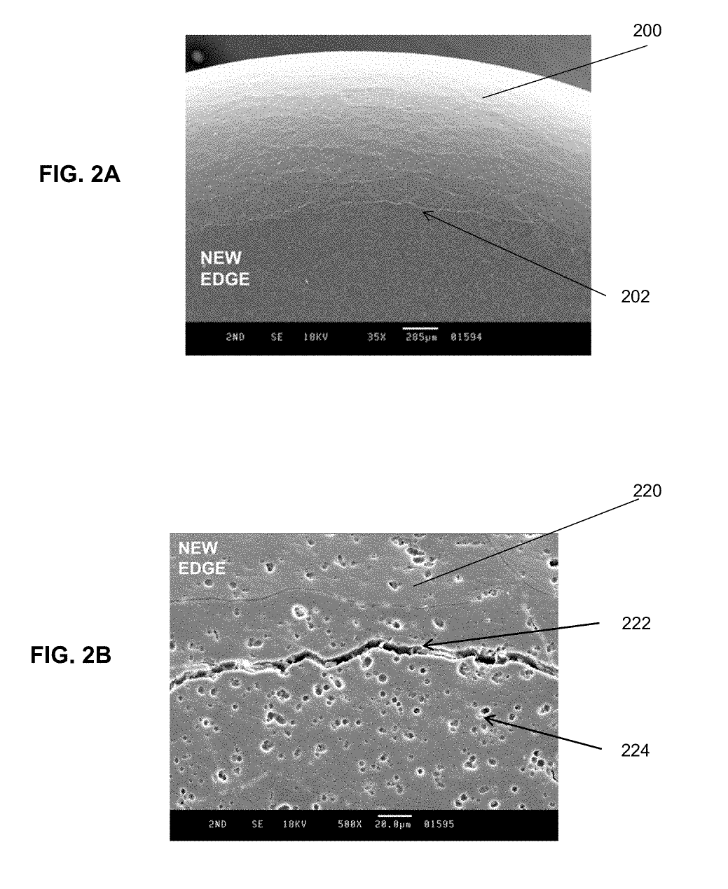

FIG. 2A is an exemplary scanning electron microscopy (SEM) image of a curved (radius of about 0.07 inch) metallic structure 200 with an anodization coating on the surface of the structure, according to an illustrative embodiment. The image is shown at a low resolution. Anodization coating can introduce different types of surface defects such as crazings (e.g., cracks) and/or pits. Crazing is a network of lines or cracks appearing on the surface of a coated metal. Crazings can be caused by thermal mismatch between the base metal and the coating due to the differences in the coefficients of thermal expansions (CTE) of the two materials of the components. The residual stress introduced during a machining process can also lead to crazings. Pits can be caused by alloy elements from the base metal that are not anodized, by contaminants left on the base metal surface prior to anodizing, or by the non-smooth machining surface. As shown in FIG. 2A, cracks 202 can be observed on the surface of the anodized metallic structure 200.

FIG. 2B is another exemplary SEM image of a curved metallic structure 220 with an anodization coating on the surface of the structure, according to an illustrative embodiment. The image is shown at a higher magnification. Cracks 222 and pits 224 can be present on the surface of the anodization coating. In some instances, cracks can penetrate through the anodization layer and down to the underlying metallic structure. These defects can be enhanced by exposure to plasma or reactive gases (or gaseous radicals) and/or corroding liquid reagents used in a semiconductor process. The enhanced defects can reduce the lifetime of the semiconductor component.

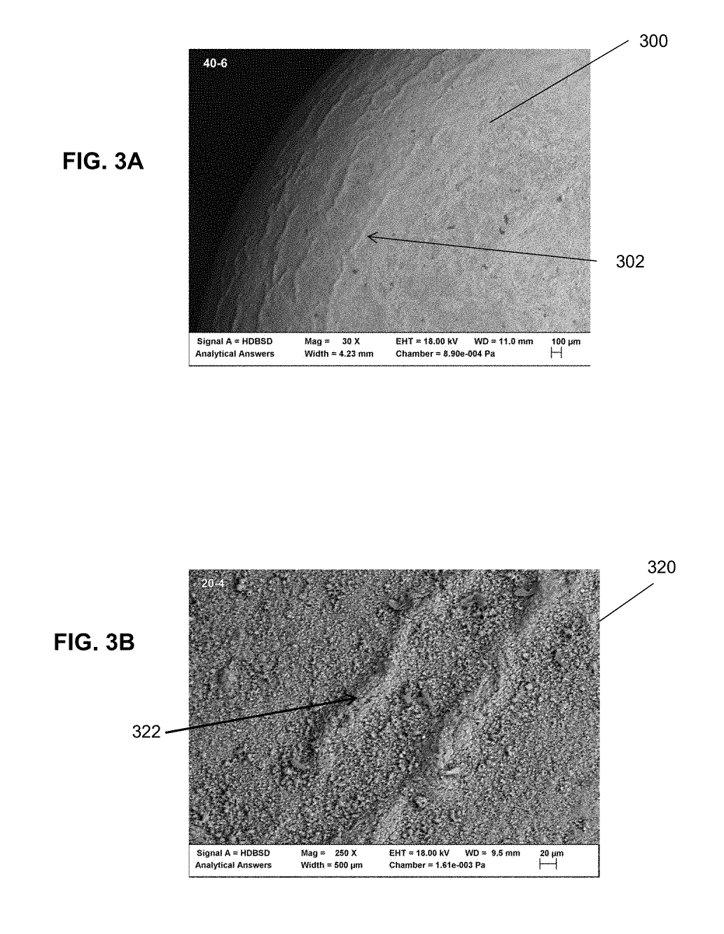

FIG. 3A is an exemplary SEM image of a curved (radius=0.07 inch) metallic structure 300 with a protective oxide layer formed by PEO after anodization of the metallic structure, according to an illustrative embodiment. For example, the PEO process can be performed on the anodized metallic structure 200 of FIG. 2A or the anodized metallic structure 220 of FIG. 2B. The PEO process can convert at least a portion of the anodization coating on the surface of the anodized metallic structure to an oxide coating. The image is shown at a low resolution. As shown, the cracks on the previous anodization layer (e.g., crack 202 of FIG. 2A) are replaced by ridge-like structures 302 on an oxide layer after the PEO process. These ridge-like structures 302 on the oxide layer can occur at positions that vertically align with the cracks 202 in the anodization layer.

FIG. 3B is another exemplary SEM image of a curved metallic structure 320 with a protective oxide layer formed by PEO after anodization of the metallic structure, according to an illustrative embodiment. One or more ridge-like structures 322 are formed on the surface of the anodized metallic structure 320 on the oxide layer after the PEO process. The ridges 322 are substantially aligned with respective ones of the cracks in the anodized layer. No visible cracks and pits can be observed in the finished oxide layer by PEO after anodization. The defect-free surface can greatly improve the performance and life span of the semiconductor components by preventing further damages to the surface of the coating.

In some embodiments, after applying the anodization process (step 104) and the PEO process (step 106) to the metallic structure, the resulting surface of the metallic structure can be textured, but still maintain its generally planar surface. The microscopic surface roughness of the metallic structure after both the anodization and the PEO processes can be further smoothed by an optional mechanical process such as polishing, thereby reducing the actual surface area exposed to the plasma or the downstream process effluent.

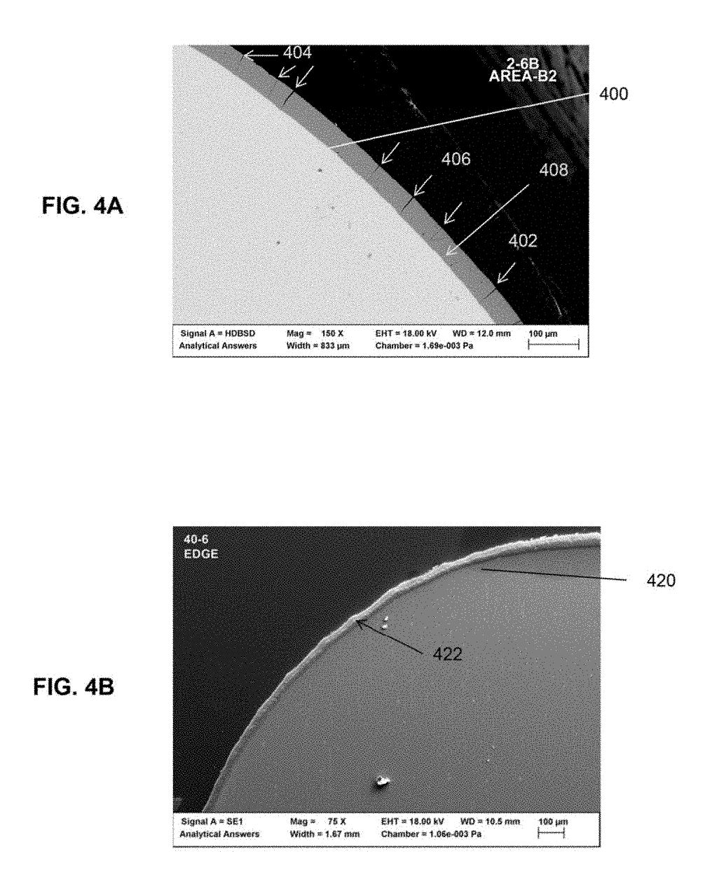

FIG. 4A is an exemplary cross-sectional view of an SEM image of a curved metallic structure 400 with an anodization layer 408 on the surface of the metallic structure 400, but without an oxide layer formed by PEO, according to an illustrative embodiment. As shown, numerous vertical cracks 402 are present in the anodization layer 408. The cracks 402 can extend over substantially the entire thickness of the anodization layer 408 or at least penetrate partially into the anodization layer 408. For example, some cracks 404 are shallow at the surface of the anodization layer 408, while other cracks 406 are substantially as deep as the thickness of the anodization layer 408.

FIG. 4B is an exemplary cross-sectional view of an SEM image of a curved metallic structure 420 with a protective oxide layer formed by PEO after anodization of the metallic structure 420, according to an illustrative embodiment. As shown, no noticeable defects (e.g., cracks or pits) can be observed in the finished protective oxide layer 422 by PEO after anodization. This is because the cracks and/or pits from the anodization layer are filled during the PEO process by the oxide layer 422.

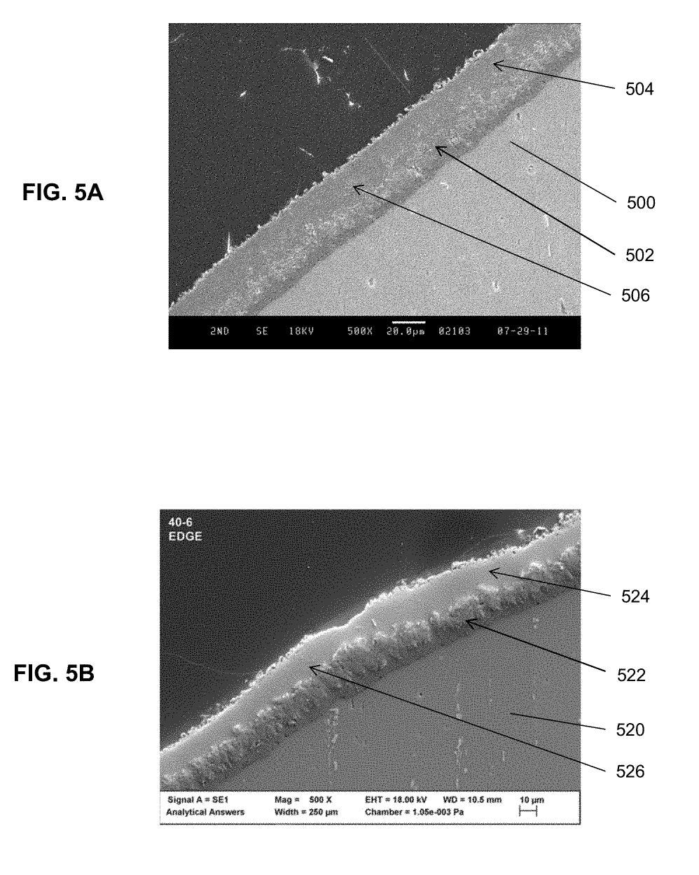

FIG. 5A is an exemplary cross-sectional view of an SEM image of a curved metallic structure 500 with a protective oxide layer 506 formed by a traditional PEO process on the un-anodized base metallic structure 500. As shown, the oxide layer 506 includes a crystalline sub-layer 502 in the lower portion of the oxide layer 506 adjacent to (i.e., immediately on top of) the surface of the base metallic structure 500. The crystalline sub-layer 502 can be made mainly of α-alumina. The oxide layer 506 also includes an outer sub-layer 504 above the dense crystalline sub-layer 502. Hence, the crystalline sub-layer 502 is positioned between the outer sub-layer 504 and the base metallic structure 500.

FIG. 5B is an exemplary cross-sectional view of an SEM image of a curved metallic structure 520 with a protective oxide layer 526 formed by PEO after anodization of the base metallic structure 520, according to an illustrative embodiment. The finished oxide layer 526 includes a crystallized dense structure 522 similar to the crystal sub-layer 502 of the oxide layer 506 formed by the traditional PEO process of FIG. 5A. The crystalline structure 522 is present in the lower portion of the oxide layer 526 adjacent to the base metallic structure 520. The crystalline structure 522 can be made mainly of α-alumina. The oxide layer 526 can also include an outer sub-layer 524 above the dense crystalline sub-layer 522.

The protective oxide layer 526, which includes the dense crystalline sub-layer 522, is robust and erosion resistant. The erosion resistant protective oxide layer 526 can reduce coating damage and particle exfoliation and therefore lead to longer product life time. Compared with a traditional PEO process without prior anodization, the PEO process after anodization, such as using the method 100 described in FIG. 1, retains the same advantage of providing a robust and erosion resistant protective oxide layer as the traditional PEO process. In addition, the PEO process after anodization offers the additional advantage of reduced surface metal concentrations as further described below.

As described above, at least a portion of a protective oxide layer forming a surface of a wall of a chamber, such as a plasma chamber or a semiconductor processing chamber, may gradually erode when exposed to corrosive conditions during use. This means that different depths of the original protective layer can form the surface of the chamber wall and be exposed to an interior of the chamber over time as the protective layer is gradually removed. Thus, the risk of metal contamination at a particular point in time depends on the metal concentration that is exposed at the surface of the protective layer at that point in time. Although the protective layer is not removed or “lost” at a uniform rate at all exposed areas of the chamber wall, portions of the chamber wall are likely to experience the same rate of loss or removal of the protective layer. If the concentration of metal in the protective layer has a maximum, which corresponds to a particular depth, the highest risk of metal contamination can occur when that particular depth of the protective layer is exposed as the surface of the chamber wall. Thus, maintaining an acceptably low risk of metal contamination over the working lifetime of a protective coating on a chamber wall involves reducing the maximum metal concentration at least in portions of the protective layer that may be exposed during the working lifetime of the protective layer.

Metal contaminations such as iron, manganese and copper have an impact on the recombination of atomic species on the plasma-facing and downstream surfaces. To minimize this impact of surface radical recombination, contents of the metal contaminations need to be reduced in the coating oxide layer. Lower surface recombination of atomic species can increase the flux of atomic species and therefore improve the process rate.

Reduced metal contamination can also reduce the contamination transported from the chamber surface to wafers in a semiconductor process. The reduced contamination in wafers can lead to better performance for use in the semiconductor manufacturing processes.

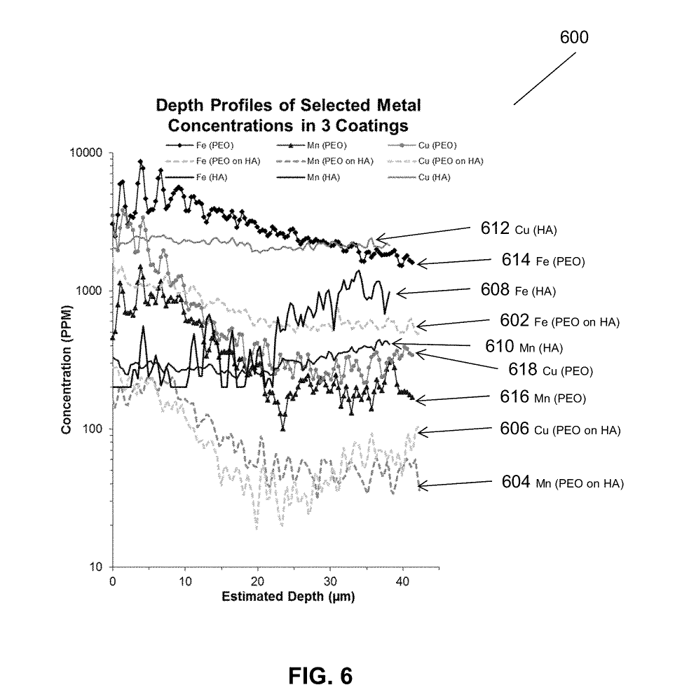

FIG. 6 is a graph 600 of concentrations of iron, manganese, and copper as a function of depth in three samples, according to an illustrative embodiment. Each sample includes a base metallic structure made of aluminum 6061 alloy (Al 6061) with an oxide coating formed from one of three different approaches. One approach forms the oxide coating over the base metallic structure using a PEO process after hard anodization of the base metallic structure (sample A). The second approach uses a conventional hard anodization process to form the oxide coating (sample B). The third approach uses a conventional PEO process to form the oxide coating (sample C). The oxide coatings in these samples are about 50 microns thick. Al 6061, which is a commonly used alloy for walls of deposition chambers, includes about a maximum of 0.7% iron, about a maximum of 0.15% manganese, and between about 0.15% and about 0.40% copper. The resulting oxide coatings formed from all three approaches include oxides of iron, manganese, and copper.

In graph 600, the concentration of iron, manganese, and copper in parts per million (ppm) are shown as a function of depth in the oxide layer (coating) as measured using laser ablation inductively coupled plasma mass spectroscopy (LA-ICP-MS). The concentrations are shown in parts per million by weight of the oxide layer material (i.e., concentration measurements that correspond to the oxide layer of the sample).

Sample A includes a protective oxide layer formed by a PEO process after a hard anodization process, such as using the method 100 described in FIG. 1. The iron concentration of the oxide layer in Sample A is indicated by line 602. The maximum iron concentration in the oxide layer, which occurs at the surface of the oxide layer, is about 1700 ppm (about 0.17% of the oxide layer of the sample at a particular depth). The manganese concentration of the oxide layer in Sample A is indicated by line 604. The manganese concentration at the surface is about 150 ppm (about 0.015%). The maximum manganese concentration, which is located at a depth of about 6-10 microns from the surface of the oxide layer, is about 220 ppm (about 0.022%). The copper concentration of the oxide layer in Sample A is indicated by line 606. The maximum copper concentration in the oxide layer, which occurs at the surface of the oxide layer, is about 270 ppm (about 0.027%).

Sample B includes a protective oxide layer formed by a hard anodization process without a subsequent PEO process. The iron concentration of the oxide layer in Sample B is indicated by line 608. The iron concentration at the surface is about 200 ppm (about 0.020% of the oxide layer of the sample at a particular depth). The maximum iron concentration in the oxide layer, which is located at a depth of about 34 microns from the surface of the oxide layer, is about 1300 ppm (about 0.13%). The manganese concentration of the oxide layer in Sample B is indicated by line 610. The manganese concentration at the surface is about 310 ppm (about 0.031%). The maximum manganese concentration in the oxide layer, which is located at a depth of about 37 microns from the surface of the oxide layer, is about 430 ppm (about 0.043%). The copper concentration of the oxide layer in Sample B is indicated by line 612. The copper concentration at the surface is about 2000 ppm (about 0.20%). The maximum copper concentration in the oxide layer, which is located at a depth of about 37 microns from the surface of the oxide layer, is about 2300 ppm (about 0.23%).

Sample C includes an oxide layer formed by a traditional PEO process without converting an anodization layer. The iron concentration of the oxide layer in Sample C is indicated by line 614. The iron concentration at the surface is about 3000 ppm (about 0.30% of the oxide layer of the sample at a particular depth). The maximum iron concentration in the oxide layer, which is located at a depth of about 4 microns from the surface of the oxide layer, is about 9000 ppm (about 0.90%). The manganese concentration of the oxide layer in Sample C is indicated by line 616. The manganese concentration at the surface is about 440 ppm (about 0.044%). The maximum manganese concentration in the oxide layer, which is located at a depth of about 5 microns from the surface of the oxide layer, is about 1600 ppm (about 0.16%). The copper concentration of the oxide layer in Sample C is indicated by line 618. The copper concentration at the surface is about 3400 ppm (about 0.34%). The maximum copper concentration in the oxide layer, which is located at a depth of about 2 microns from the surface of the oxide layer, is about 3900 ppm (about 0.39%).

LA-ICPMS depth profiles shown in FIG. 6 indicate that the concentrations of metals, such as Fe, Cu, and Mn, in the protective oxide layer formed by a PEO process after anodization of the metallic substrate (hereinafter referred to as the “new coating”) are significantly reduced compared to the coating formed by a traditional PEO process without anodization (hereinafter referred to as the “traditional PEO coating”). For example, surface iron concentration for the new coating is about 57% of that for a traditional PEO coating. Surface manganese concentration for the new coating is about 34% of that for a traditional PEO coating. Surface copper concentration for the new coating is about 7.9% of that for a traditional PEO coating. Further, the maximum iron concentration for the new coating is about 19% of that for a traditional PEO coating. The maximum manganese concentration for the new coating is about 14% of that for a traditional PEO coating. And the maximum copper concentration for the new coating is about 6.9% of that for a traditional PEO coating.

During the discharging process in a traditional PEO approach, the localized high temperature and high pressure allow the alloying elements of the base metallic structure to melt or diffuse into discharge channels. Those alloying elements can re-solidify after rapid cooling. Compared to an oxide coating generated from a traditional hard anodization process, a traditional PEO coating often shows much higher metal concentrations. Some metals have uneven distribution through the entire PEO coating. Generally, the surface concentration and maximum concentration of metals occurring at the surface or near surface of a traditional PEO coating increase the risk of metal contamination to an unacceptable level for many semiconductor processing applications.

The new coating (i.e., the protective oxide layer formed by a PEO process after an anodization process) results in both lower metal concentration on the surface and lower maximum metal concentration in the oxide coating. Lower metal contamination concentration can lead to lower surface recombination and high flux of atomic species. The lower metal contamination concentration also reduces the contamination transported from the coating surface to the wafers in a semiconductor process. Furthermore, the new coating is more robust and erosion resistant, which greatly increases the lifetime of a semiconductor processing component and lowers ownership cost.

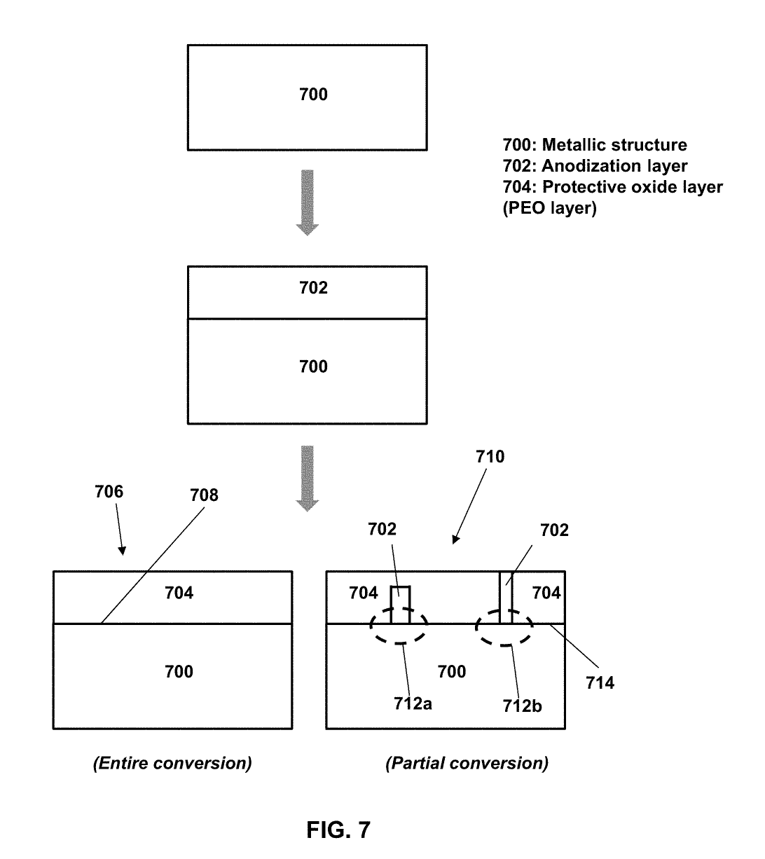

FIG. 7 is an illustration of different layering structures that can be formed by the method 100 of FIG. 1. An anodization layer 702 is formed on top of a metallic structure 700 (i.e., a metallic substrate), such as using step 104 of method 100. A PEO process is then applied to the anodized metallic structure, such as using step 106 of method 100. In some embodiments, substantially the entire anodization layer 702 is converted by the PEO process to a protective oxide layer 704, as illustrated by the layered structure 706. Therefore, the resulting protective oxide layer 704 of the layered structure 706 is directly on top of the metallic structure 700. For example, the oxide layer 704 of the layered structure 706 can have a substantially uniform thickness and maintains a substantially planar physical interface 708 with the underlying metallic structure 700.

In some other embodiments, as shown in the layered structure 710, the physical interface 714 between the oxide layer 704 and the metallic structure 700 is irregular and can be interrupted by one or more areas (e.g., areas 712a and 712b) with the anodization layer 702 still remaining after PEO. That is, the PEO process cannot completely convert the anodization layer of the anodized metallic structure, thereby leaving at least a portion of the anodization layer 702 intact after the PEO process. For example, when irregular features exist in the metallic structure 700 which can be inherent in the underlying metallic structure, such as deep holes with small diameters (e.g. holes with diameter less than 5 millimeter and depth more than 6 millimeter), a PEO layer can be difficult to form in these deep and narrow structures. Those irregular features can have weaker electric field and lower electrolyte flow rate that discourage PEO layer formation. However, an anodization process can typically reach and form an anodization coating on the surface of those irregular features in the metallic base 700. As shown in the layered structure 710, the metallic structure 700 includes two irregular features at areas 712a and 712b that can be covered by an anodization coating not fully converted by the subsequent PEO process. In these areas, little or no oxide layer 704 overlays the base metallic structure 700. For example, in the area 712b, the PEO process cannot convert the anodization layer 702 such that no oxide layer 704 is generated in that area 712b and only the anodization layer 702 directly covers the metallic structure 700. In the area 712a, the PEO process only converts a portion of the thickness of the anodization layer such that both an oxide layer 704 and an anodization layer 702 are above the metallic structure 700 in that area 712a.

Thus, the metallic structure 700 of the layered structure 710 is protected by at least one of the protective oxide coating formed at step 106 of method 100 or the residual anodization coating formed at step 104 of method 100. Therefore, by having the anodized coating as the base layer on which PEO is initiated, any weak spots of the base metallic structure that cannot be fully converted to PEO coating can still be protected by the anodized layer. This type of coverage reduces the opportunity of arcing and particle generation. Such irregular coverage can also be applied on interior surfaces and/or surfaces of complex geometries.

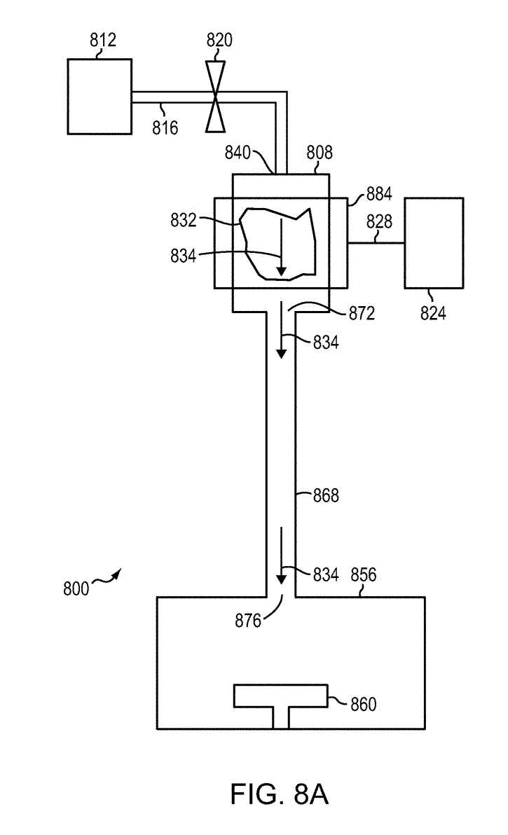

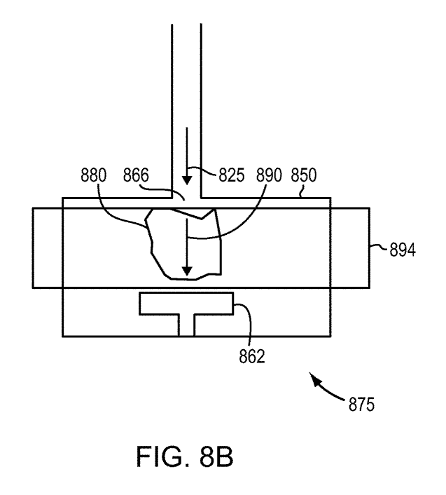

Embodiments described above are mostly directed to methods of making oxide layers over surfaces of objects and methods of treating objects. Additional embodiments include plasma chambers having plasma chamber walls with protective coatings and semiconductor process chambers having chamber walls with protective coatings, in accordance with other aspects of the invention. For example, FIG. 8A is partial schematic representation of a reactive gas generator system 800 for exciting gases that includes an exemplary plasma chamber. The reactive gas generator system 800 includes a plasma gas source 812 connected via a gas line 816 to an inlet 840 of the plasma chamber 808. A valve 820 controls the flow of plasma gas (e.g., O₂, N₂, Ar, NF₃, F₂, H₂, NH₃, and He) from the plasma gas source 812 through the gas line 816 and into the inlet 840 of the plasma chamber 808. A plasma generator 884 generates a region of plasma 832 within the plasma chamber 808. The plasma 832 comprises the plasma excited gas 834, a portion of which flows out of the chamber 808. The plasma excited gas 834 is produced as a result of the plasma 832 heating and activating the plasma gas. The plasma generator 884 may be located partially around the plasma chamber 808, as shown.

The reactive gas generator system 800 also includes a power supply 824 that provides power via connection 828 to the plasma generator 884 to generate the plasma 832 (which comprises the excited gas 834) in the plasma chamber 808. The plasma chamber can have a plasma chamber wall including a base metallic alloy material (e.g., an aluminum alloy) and a protective oxide layer produced using a PEO process after an anodization process illustrated by diagram 100 in FIG. 1. The protective oxide layer produced by process 100 has significantly lower concentrations of metals, such as Fe, Cu, and Mn, compared to the coating formed by a traditional PEO process.

The plasma chamber 808 has an outlet 872 that is connected via a passage 868 to an input 876 of a semiconductor process chamber 856. The excited gas 834 flows through passage 868 and into the input 876 of the process chamber 856. A sample holder 860 positioned in the process chamber 856 supports a material that is processed by the excited gas 834. The excited gas 834 may facilitate processing of a semiconductor wafer located on the sample holder 860 in the process chamber 856.

In yet another embodiment, the semiconductor process chamber 856 includes a base structure (i.e., substrate) of a metallic alloy material and a protective oxide layer produced using a PEO process after an anodization process illustrated by diagram 100 in FIG. 1. The protective oxide layer produced by process 100 has significantly lower concentrations of metals, such as Fe, Cu, and Mn, compared to the coating formed by a traditional PEO process. As noted above, the process chamber has an input or inlet for receiving an excited gas or a plasma.

The plasma source 884 can be, for example, a DC plasma generator, radio frequency (RF) plasma generator or a microwave plasma generator. The plasma source 884 can be a remote plasma source. By way of example, the plasma source 884 can be an ASTRON® or Paragon® remote plasma source manufactured by MKS Instruments, Inc. of Andover, Mass.

In one embodiment, the plasma source 884 is a toroidal plasma source and the chamber 808 is a chamber made from an aluminum alloy. In other embodiments, alternative types of plasma sources and chamber materials may be used.

The power supply 824 can be, for example, an RF power supply or a microwave power supply. In some embodiments, the plasma chamber 808 includes a means for generating free charges that provides an initial ionization event that ignites the plasma 832 in the plasma chamber 808. The initial ionization event can be a short, high voltage pulse that is applied to the plasma chamber 808. The pulse can have a voltage of approximately 500-10,000 volts and can be approximately 0.1 microseconds to 100 milliseconds long. A noble gas such as argon can be flowed into the plasma chamber 808 to reduce the voltage required to ignite the plasma 832. Ultraviolet radiation also can be used to generate the free charges in the plasma chamber 808 that provide the initial ionization event that ignites the plasma 832 in the plasma chamber 808.

The reactive gas generator system 800 can be used to excite a gas comprising halogen for use. An object comprising aluminum, magnesium, titanium, or yttrium can be processed using an anodization followed by a PEO process (e.g., steps 102-106 of FIG. 1) to oxidize at least one surface of the object forming an oxidized layer. In addition, one or more of the above described methods, techniques or processes for reducing the contamination metal concentration is employed in the formation or processing of the oxidized layer.

In one embodiment, the oxidized object was installed in the plasma chamber 808 and exposed to the plasma 832. In one embodiment, an ASTRON® or Paragon® remote plasma source manufactured by MKS Instruments, Inc. of Andover, Mass. was used as the plasma source 884.

In another embodiment, the reactive gas generator system 800 is used to excite a gas comprising halogen. In some embodiments, the plasma chamber 808 is the object that is processed using a PEO process after an anodization process (e.g., step 102-106 of FIG. 1). In this embodiment, the plasma chamber 808 is constructed from an aluminum alloy that includes iron, manganese and copper. An anodization process followed by a PEO process is used to create the oxide layer on the interior surfaces of the plasma chamber 808. One of the various disclosed methods, techniques or processes for reducing a contamination metal concentration during the formation or subsequent processing of the oxide layer is employed. In some embodiments, after surfaces of the plasma chamber are oxidized, the plasma chamber 808 is then installed in the reactive gas generator system 800.

The plasma gas source 812 provides plasma gas to the plasma chamber 808. Plasma 832 is generated. The plasma 832 generates the excited plasma gas 834 in the chamber 808. The oxidized interior surfaces of the plasma chamber 808 are therefore exposed to plasma 832 and excited gas 834. The oxidized surfaces of the plasma chamber 808 are exposed to the plasma 832 and excited gas 834.

The reactive gas generator system 800 may be used to create plasma 832 by exciting a gas comprising halogen. The interior surfaces of gas passage 868 and/or process chamber 856 are the objects processed using a PEO process after an anodization process (e.g., e.g., steps 102-106 of FIG. 1). In this embodiment, the gas passage 868 and/or process chamber 856 are constructed from a metallic alloy. An anodization process followed by a PEO process is used to create the oxide layer on the interior surfaces of passage 868 or process chamber 856. One of the various methods, techniques or processes for reducing a contamination metal concentration during the formation or subsequent processing of the oxide layer is employed. The plasma chamber 808 is installed in the reactive gas generator system 800. The plasma gas source 812 provides plasma gas to the plasma chamber 808. Plasma 832 is generated. The plasma 832 generates the excited plasma gas 834 which subsequently flows through passage 868 and process chamber 856. The oxidized interior surfaces of the passage 868 and process chamber 856 are therefore exposed to the excited gas 834.

FIG. 8B is partial schematic representation of an in-situ plasma system 875. The plasma gas 825 (e.g., a gas comprising a halogen) is provided, via input 866, to the plasma chamber 850, which is also the process chamber. In the embodiment of FIG. 8B, the plasma chamber is also a process chamber. Other embodiments may include a plasma reactor that is remote from the process chamber.

In one embodiment, the process chamber 850 is constructed from a metallic alloy. In some instances, the metallic alloy is an aluminum alloy. In some instances, the metallic alloy includes metals such as Fe, Mn and Cu. A PEO process after an anodization process (e.g., steps 102-106 of FIG. 1) is used to create the oxide layer on the interior surfaces of process chamber 850. One of the various methods, techniques, or processes for reducing a contamination metal concentration during the formation or subsequent processing of the oxide layer is employed. The protective oxide layer produced by process 100 has significantly lower concentrations of metals, such as Fe, Cu, and Mn, compared to the coating formed by a traditional PEO process.

In some embodiments, the process chamber 850 itself may be the object. A plasma 880 is generated inside the chamber 850 by a plasma reactor 894. A surface of the process chamber 850 has a protective oxide layer created by process 100 with a low or reduced peak contamination metal concentration. A plasma 880 is generated inside the chamber 850 by a plasma reactor 894.

In some embodiments, the process chamber is used for processing of a sample which is the object. A sample holder 862 positioned in the process chamber 850 supports a material that is processed by the plasma 880 and excited gas 890. In one embodiment, the object having a surface protective oxide layer created by process 100 is placed on the sample holder 862 and exposed to the plasma 880 and/or excited gas 890. In the embodiment depicted in FIG. 8B, a plasma 880 is generated inside the chamber 850 by a plasma reactor 894. The object is constructed from a metallic alloy. In some instances, the metallic alloy is an aluminum alloy. In some instances, the metallic alloy includes metals such as Fe, Mn and Cu. An anodization process followed by a PEO process is used to create the oxide layer on the object. One of the various methods, techniques, or processes for reducing a contamination metal concentration during the formation or subsequent processing of the oxide layer is employed. The protective oxide layer produced by process 100 has significantly lower concentrations of metals, such as Fe, Cu, and Mn, compared to the coating formed by a traditional PEO process.

The protective oxide layer produced by process described herein (e.g. 102-106 of FIG. 1) can be used in a variety of applications. In some embodiments, the protective oxide layer can be used in a system where atomic hydrogen sources are implemented for native oxide cleaning processes from a semiconductor or metallic surface. In some embodiments, the protective oxide layer can be used in a system, especially in the plasma source, where atomic hydrogen source is utilized for photoresist ashing. In some cases, hydrogen radicals may be preferred over fluorine radicals to minimize the over etching and oxidation of the substrates and/or underlying layers especially for low-k dielectrics, once the photoresist is removed by oxygen radical based ashing processes. In another example, the protective oxide layer can be used in a system, especially on the plasma source, where a carbonized crust removal process is applied after a high dose implant. The use of the protective oxide layer on the plasma source enables the plasma source to have lower radical losses due to lower surface recombinations than a plasma source having only a standard PEO coating. The use of the atomic hydrogen source can prevent the oxidation of exposed source, drain, and/or gate that can otherwise be oxidized via O₂-based ashing processes. Such oxidation can lead to etching of those materials in subsequent wet cleans which can cause undesirable device performance shifts.

In some embodiments, the protective oxide layer can be used in a system especially in the plasma source where dissociated H₂ and NH₃ gases provide radicals for dielectric deposition processes. In some embodiments, the protective oxide layer can be used in a system where atomic chlorine or fluorine source is used for chamber clean. For example, the protective oxide layer can be used in a III-nitride metal-organic chemical vapor deposition (MOCVD) equipment for light-emitting diode (LED) fabrication. In another example, the protective oxide layer can be used in deposition chamber clean processes for which chlorine by-products have higher vapor pressures than the corresponding fluorine by-products. The metal alloy materials used in such a chamber clean process include, e.g., Hf, Ta, Ti, Ru, Sn, In, Al, and/or Ga. In some embodiments, the protective oxide layer can be used in some other etch processes that use other halogen radicals, such as F, Br and Cl usually in combination with carbon and/or oxygen containing molecules.

In some other embodiments, the protective oxide layer produced by process described herein (e.g. steps 102-106 of FIG. 1) can be used as coatings for components that are exposed to high radical fluxes and need to withstand thermal cycling without deterioration. Those components include, for example, plasma chamber walls and liners, showerheads, radical transport tubes, exhaust lines, plasma applicators, and/or large area of the plasma source such as the top lid. In some instances, the protective oxide layer can be used in an ASTRON® product with an aluminum based plasma applicator manufactured by MKS Instruments, Inc. of Andover, Mass. In some embodiments, the protective oxide layer can be used as coatings for other components such as isolation or gate valve components that are in the wetted path for radical transport. The use of the protective oxide layer can minimize recombination losses and thus limit the temperature rise of these components.

Variations, modifications, and other implementations of what is described herein will occur to those of ordinary skill in the art without departing from the spirit and the scope of the invention as claimed. Accordingly, the invention is to be defined not by the preceding illustrative description but instead by the spirit and scope of the following claims.

1. A method for fabricating a protective oxide layer over a surface of a metallic alloy structure used in a semiconductor processing system, the method comprising:
providing the metallic alloy structure;
anodizing the surface of the metallic alloy structure to form an anodization layer on the surface using an acidic electrolyte; and
converting, using an alkaline electrolyte in a plasma electrolytic oxidation process, at least a portion of the anodization layer to form the protective oxide layer,
wherein a metal concentration of the protective oxide layer is minimized to reduce recombination of atomic species on a surface of the protective oxide layer.

2. The method of claim 1, wherein the surface of the metallic alloy structure comprises at least one of aluminum, magnesium, titanium, or yttrium.

3. The method of claim 1, wherein the converting of at least a portion of the anodization layer comprises converting, using the plasma electrolytic oxidation process, substantially an entire thickness of the anodization layer to form the protective oxide layer over the surface of the metallic alloy structure.

4. The method of claim 1, wherein the surface of the metallic alloy structure is directly covered by the protective oxide layer from the plasma electrolytic oxidation process at a first location and directly covered by the anodization layer from the anodizing at a second location.

5. (canceled)

6. The method of claim 1, wherein the protective oxide layer is substantially free of one or more defects in the anodization layer.

7. The method of claim 1, further comprising forming a plurality of surface ridges protruding from the protective oxide layer, the plurality of surface ridges substantially align with corresponding ones of a plurality of defects in the anodization layer.

8. A coated metallic structure used in a plasma processing equipment, comprising:
a metallic alloy structure; and
a protective oxide layer formed over a surface of the metallic alloy structure, the protective oxide layer formed by (i) anodizing the surface of the metallic alloy structure to generate an anodized layer using an acidic electrolyte and (ii) converting substantially all of the anodized layer using an alkaline electrolyte in a plasma electrolytic oxidation process,
wherein the protective oxide layer is characterized by a plurality of surface ridges protruding from the protective oxide layer and a metal concentration of the protective oxide layer is minimized to reduce recombination of atomic species on a surface of the protective oxide layer.

9. The coated metallic structure of claim 8, wherein the protective oxide layer is generally planar.

10. The coated metallic structure of claim 8, wherein the plurality of surface ridges are substantially aligned with respective ones of a plurality of cracks formed in the anodized layer.

11. The coated metallic structure of claim 8, wherein a surface of the protective oxide layer is planarized by mechanical processing.

12. The coated metallic structure of claim 8, wherein the protective oxide layer formed from the plasma electrolytic oxidation process directly covers the surface of the metallic alloy structure at a first surface location and the anodized layer formed from the anodizing directly covers the surface of the metallic alloy structure at a second surface location.

13. A component comprising a metallic alloy layer and a protective oxide layer over a surface of the metallic alloy layer, the component formed by the process of:
providing the metallic alloy layer;
forming an anodization layer on the surface of the metallic alloy layer by anodizing the surface using an acidic electrolyte; and
converting, using an alkaline electrolyte in a plasma electrolytic oxidation process, at least a portion of the anodization layer to form the protective oxide layer over the surface of the metallic alloy layer,
wherein a metal concentration of the protective oxide layer is minimized to reduce recombination of atomic species on a surface of the protective oxide layer.

14. (canceled)

15. The component of claim 13, wherein the metallic alloy layer comprises an aluminum alloy.

16. The component of claim 13, wherein the surface of the metallic alloy layer comprises at least one of aluminum, magnesium, titanium, or yttrium.

17. The component of claim 13, wherein the forming of an anodization layer comprises anodizing the surface by a hard anodization process.

18. The component of claim 13, wherein a thickness of the anodization layer is less than 130 microns.

19. The component of claim 18, wherein the thickness of the anodization layer is between about 12 to about 120 microns.

20. The component of claim 13, wherein the converting of at least a portion of the anodization layer comprises converting, using the plasma electrolytic oxidation process, substantially an entire thickness of the anodization layer to form the protective oxide layer over the surface of the metallic alloy layer.

21. The component of claim 13, wherein the protective oxide layer is substantially free of one or more defects in the anodization layer.

22. The component of claim 13, wherein the protective oxide layer includes a partially crystallized dense structure formed adjacent to the metallic alloy layer.

23. The component in claim 13, wherein the protective oxide layer is corrosion and erosion resistant.

24. The component in claim 13, wherein the protected oxide layer is in contact with a plasma in a plasma processing chamber.

25. The component in claim 13, wherein the protected oxide layer is in contact with a reactive gas or gaseous radicals in a semiconductor processing chamber.

26. The component in claim 13, wherein the protected oxide layer is in contact with a corroding liquid reagent in a semiconductor processing chamber.

27. A method for fabricating a protective oxide layer over a surface of a metallic structure used in a semiconductor processing system, wherein at least a portion of the surface of the metallic structure is curved, the method comprising:
providing the metallic structure;
anodizing the curved surface of the metallic structure to form an anodization layer on the surface using an acidic electrolyte;
converting, using an alkaline electrolyte in a plasma electrolytic oxidation process, at least a portion of the anodization layer on the curved surface of the metallic structure to form the protective oxide layer; and
forming a plurality of surface ridges protruding from the protective oxide layer, wherein the plurality of surface ridges are aligned with corresponding ones of a plurality of cracks in the anodization layer over the curved surface of the metallic structure.
